(19) United States
(12) Patent Application Publication
(10) Pub. No.: US 2016/0059261 A1
(43) Pub. Date: Mar. 3, 2016

(54) GAS BARRIER FILM AND METHOD FOR PRODUCING THE SAME

(71) Applicant: KONICA MINOLTA, INC., Tokyo (JP)

(72) Inventor: Shoji Nishio, Tokyo (JP)

(73) Assignee: KONICA MINOLTA, INC., Tokyo (JP)

(21) Appl. No.: 14/888,332

(22) PCT Filed: Apr. 24, 2014
(86) PCT No.: PCT/JP2014/061624

§ 371 Date: Oct. 30, 2015

(30) Foreign Application Priority Data
May 1, 2013 (JP) 2013-096587

(51) Int. Cl. B05D 3/06; H01L 51/52; C23C 16/40; C23C 14/34; C23C 16/513; C23C 16/30

(52) U.S. Cl. CPC B05D 3/065; C23C 16/513; C23C 16/30; C23C 16/402; C23C 14/34; H01L 51/5256

(57) ABSTRACT

A gas barrier film includes a first barrier layer formed by a vapor deposition method on at least one side of a substrate. The gas barrier film includes a second barrier layer formed on the first barrier layer by converting a polysilazane coating film. The polysilazane coating film includes one type of nanoparticles. The nanoparticles include metal oxide or metal nitride. The polysilazane coating film is converted by irradiating the polysilazane coating film with vacuum UV ray having a wavelength of 200 nm or less.

### TECHNICAL FIELD

Embodiments of the invention relate to a gas barrier film and a method for producing the same. In more detail, embodiments relate to a gas barrier film having excellent adhesion of a barrier layer, and low vapor and oxygen permeability, and also, an electronic device using such a gas barrier film, and particularly, an image display device such as an organic EL device (organic electroluminescent device).

### BACKGROUND ART

Conventionally, a gas barrier film produced by forming a metal oxide thin film such as aluminum oxide, magnesium oxide, and silicon oxide, on a plastic substrate or film surface is widely used for an use of packing an article to be needed for blocking various gases such as vapor or oxygen, and a package use for preventing food, supplies for industry, and medicine and medical supplies from deteriorating. Furthermore, in addition to a packaging use, the development of flexible electronic devices such as a flexible solar battery element, a liquid crystal display element, and an organic electroluminescence (hereinafter, abbreviated as an organic EL) element is requested, and thus, many examinations have been performed. However, these flexible electronic devices require gas barrier properties such as very high level of glass substrate, and thus, the gas barrier film having sufficient performance is not provided at the present time.

As a method for producing such a gas barrier film, there are known a chemical deposition method (plasma CVD method: chemical vapor deposition) including using an organic silicon compound represented by tetraethoxysilane (TEOS) and growing it on a substrate while performing an oxygen plasma oxidation under the decompression or a vapor deposition method called a physical disposition method including vaporizing metal silicon using a semiconductor laser and depositing on a substrate in the presence of oxygen.

An inorganic film-forming method according these vapor deposition methods is applied for forming an inorganic film such as silicon oxide, silicon nitride, and silicon nitride oxide, and thus, many examinations about the composition of inorganic film and the constitution of layers including these inorganic films are being performed in order to obtain good gas barrier properties.

However, it is very difficult to form the films without defects by the above-described vapor deposition methods, and thus, for example, it is required to suppress the generation of defects by extremely lowering a film-forming rate. For this reason, for an industrial level requiring productivity, the gas barrier properties that are required for a flexible electronic device are not provided. The examinations for simply increasing the film thickness of an inorganic film by a vapor deposition method or for laminating a plurality of inorganic films are performed. However, the defect thereof is continuously increased, or cracks are increased, and thus, it does not lead to improving gas barrier properties.

The defect of an inorganic film influences its own durability of device, by causing the outbreak of a sunspot that does not emit light, being called a dark spot, or growing up the size of the dark spot at a high temperature and high humidity, for example in the case of an organic EL.

Meanwhile, in the past, in addition to this vapor layer film-forming, the present inventors performed the examination for effectively restoring the defect part of the inorganic film formed by the above-described vapor-phase method and also for improving its own gas barrier properties of the film laminated by applying the solution of an inorganic precursor compound on the above-described vapor-phase-forming film, drying the film thus obtained, and converting the coating layer with heat or light, as one of the methods for forming a barrier layer. Especially, by using polysilazane as the inorganic precursor compound, the examination for exhibiting gas barrier properties in a high level by restoring the above-described defect part is being performed (JP 2012-106421 A).

Polysilazane (for example, perhydroxy polysilazane) is a compound having —(SiH₂—NH)— as a basic backbone. The polysilazane is subjected to a heat treatment or wet-heat treatment under an oxidative atmosphere, and then, is changed into silicon oxide via silicon nitride oxide. At this time, it is known that, since it is changed into silicon oxide in the state of relatively low volume contraction because of the direct substitution reaction from nitrogen to oxygen caused by oxygen or water vapor in the atmosphere, the relatively dense film with low defect in the film, which is caused by the volume contraction, is obtained. It may be possible to obtain a relatively dense silicon nitride oxide film by controlling the oxidative characteristics in the atmosphere.

However, in order to forma dense silicon nitride oxide film or silicon oxide film by a heat conversion or wet-heat conversion of polysilazane, a high temperature was required, and thus, it is difficult to apply the film on a flexible substrate such as plastic.

Embodiments of the invention include a method for forming a silicon nitride oxide film or silicon oxide film by performing the irradiation of vacuum UV ray on the coating film formed by applying the solution of polysilazane.

It becomes possible to perform the formation of a silicon nitride oxide film or silicon oxide film at a relatively low temperature by using light energy with a wavelength of 100 to 200 nm, being called vacuum UV ray (hereinafter, also referred to as “VUV” or “VUV ray”) having higher energy than the binding force between the respective atoms of polysilazane, and then, performing the oxidation reaction by active oxygen or ozone while directly cutting the binding of atoms through the action only by a photon, being called a photon process. In addition, this method is suitable for preparing a film with a roll-to-roll way with good productivity.

In detail, generally, when polysilazane is applied on a resin film substrate, and then, the irradiation of UV ray is equally performed, the vicinity of surface of irradiated side is converted to form a barrier layer (high-nitrogen-concentrated layer). At the same time, it is reported that the oxidation behavior that is presumed to be water-carried from the side of a substrate occurs, and thus, the behavior, in which the inside under the barrier layer becomes an oxide film (silicon oxide layer), occurs (for example, WO 2011/007543 A).

### SUMMARY OF INVENTION

On closer examination, the present inventors found new object, in which for the gas barrier film prepared by forming a film with the coating solution including the solution of polysilazane on a first barrier layer formed by the above-described vapor-phase method, and then, converting the polysilazane by the irradiation of UV ray to form a second barrier layer, when the gas barrier film is exposed to the environment of a high temperature and high humidity, the formed barrier layers disappear, and then, the barrier properties are significantly reduced.

Especially, they found that when having the barrier layer in the lower layer, the oxidation in the vicinity of the surface of the polysilazane film converted by the irradiation of UV ray proceeds by the effect of oxygen or water that is received from outside, but an oxygen element is not sufficiently received to the inside thereof, there are the non-converted areas that are insufficiently reacted, and these non-converted areas contribute to the deterioration of the barrier layer when being exposed to a high temperature and high humidity as described above.

An embodiment of the invention provides a barrier film capable of maintaining high barrier properties by preventing the change in composition even if being exposed to the environment of a high temperature and high humidity because the adhesion of barrier layer is excellent by forming a second barrier layer formed with the coating solution including polysilazane on a vapor deposition film.

The inventors found that for the gas barrier film having a vapor deposition film and a polysilazane converted film, at least any one type of nanoparticles among metal oxide nanoparticles and metal nitride nanoparticles is introduced into the polysilazane converted film.

In other words, embodiments of the invention relate to a gas barrier film including a first barrier layer (first inorganic layer) that is formed on at least one side of a substrate (supporting body) by a vapor deposition method and a second barrier layer (second inorganic layer) that is formed by converting the polysilazane coating film on the first inorganic layer, in which the polysilazane coating film includes at least one type of nanoparticles among metal oxide and metal nitride, and the polysilazane coating film is converted by irradiating the polysilazane coating film with vacuum UV ray having a wavelength of 200 nm or less.

### BRIEF DESCRIPTION OF THE DRAWINGS

FIG. 1 is a schematic diagram illustrating an example of vacuum plasma CVD device used for forming a first inorganic layer in accordance with one or more embodiments of the invention.

FIG. 2 is a schematic diagram illustrating an example of other producing device used for forming the first inorganic layer in accordance with one or more embodiments of the invention.

FIG. 3 is a bead mill for controlling the diameter of nanoparticle in accordance with one or more embodiments of the invention.

### DESCRIPTION OF EMBODIMENTS

Embodiments of the invention relate to a gas barrier film including a first barrier layer (first inorganic layer) that is formed on at least one side of a substrate (supporting body) by a vapor deposition method and a second barrier layer (second inorganic layer) that is formed by converting the polysilazane coating film on the first inorganic layer, in which the polysilazane coating film includes at least one type of nanoparticles among metal oxide and metal nitride, and the polysilazane coating film is converted by irradiating the polysilazane coating film with vacuum UV ray having a wavelength of 200 nm or less. According to the above-described constitution, since the smooth non-converted areas of polysilazane are reinforced by hard nanoparticles, a gas barrier film with high barrier properties under a high temperature and high humidity is provided.

When a barrier layer is formed by converting the layer through irradiating the film of polysilazane with vacuum UV ray, the surface side of the barrier layer, which is irradiated with vacuum UV ray, is converted. For this reason, it is difficult to diffuse oxygen or water in the inside of the barrier layer, and there are remained the non-reacted (non-converted) areas capable of generating ammonia by hydrolysis. These non-reacted (non-converted) areas are slowly reacted under a high temperature and high humidity to generate by-products, and then, by diffusing these by-products, there may be the cases of deforming or breaking the barrier layer. As a result, the barrier properties were slowly reduced.

In order to obtain higher gas barrier properties, it is required that the light amount of UV ray for converting the film of polysilazane is increased, and then, a plurality of barrier layers are laminated. However, because the progress degree of the conversion and the number of laminations are increased, as a film thickens, the productivity reduces and also the contraction internal stress in a film increases, thereby reducing the flexibility that is the characteristic of a flexible gas barrier film, and thus, reducing the durability to physical stress such as bending.

In contract, the gas barrier film in accordance with embodiments of the invention has excellent adhesion of barrier layers, and thus, has low vapor and oxygen permeability even under a high temperature and high humidity.

The detailed reason for the gas barrier film in accordance with embodiments of the invention that has excellent adhesion of barrier layer, and thus, has low vapor and oxygen permeability even under a high temperature and high humidity is unclear, but it is considered that the reason is as follows.

The conventional inorganic layer formed by converting the polysilazane coating film without nanoparticles has many non-converted areas including much nitrogen, which are remained. It is considered that physical and chemical strength thereof is weak, and thus, the polysilazane layer including many non-converted areas is immediately deteriorated under the wet-heat environment.

At least one type of nanoparticles in the metal oxide and metal nitride included in the coating solution including polysilazane in accordance with one or more embodiments of the invention has a functional group such as a hydroxyl group, on the surface thereof, and thus, the functional group is reacted with the Si—N bonding of polysilazane to be the state where the surface of nanoparticle is converted with polysilazane. It is considered that the second inorganic layer in accordance with one or more embodiments of the invention obtained by converting the polysilazane coating film formed by applying and drying this coating solution including polysilazane becomes the state where the smooth non-converted areas are reinforced with hard nanoparticles, thereby obtaining high strength even under a wet-heat environment. In addition, it is considered that when carbon or nitrogen is included in a vapor deposition film (first inorganic layer) in the lower layer, the first inorganic layer becomes the state that is more flexible and has improved surface reactivity, and thus, the interaction with a second inorganic layer becomes strong. It is considered that the inorganic layer that is obtained as described above has many remained nitrogen, and thus, both high gas barrier properties and wet-heat resistance can be obtained.

In addition, the above mechanism is only presumed, and embodiments of the invention are not limited to the above mechanism.

Hereinafter, embodiments of the invention will be described. In addition, the invention is not limited to the following embodiments.

In addition, in the present specification, unless otherwise noted, the “X to Y” indicating the range means “X or more and Y or less”, and the operations and the measurements of physical properties are performed under the conditions of room temperature (20 to 25° C.)/the relative humidity of 40 to 50%.

<<Gas Barrier Film>>

The gas barrier film in accordance with one or more embodiments of the invention includes a substrate and barrier layers. The gas barrier film in accordance with one or more embodiments of the invention may further include other members. The gas barrier film in accordance with one or more embodiments of the invention may include other members, for example, between a substrate and a barrier layer, between a barrier layer and a barrier layer, on a barrier layer, or the surface of a substrate without a barrier layer. Here, other members are not particularly limited, and the same members as the members that are used for a conventional gas barrier film may be used or the members that are used for a conventional gas barrier film may be properly converted and then used. In detail, there may be a smoothing layer, an anchor coat layer, a bleed-out prevention layer, a protective layer, a functionalized layer such as a moisture absorption layer or an antistatic preventing layer, and the like.

In addition, in one or more embodiments of the invention, the first barrier layer and second barrier layer may be present singly, or the laminated structure of two or more layers may be used. In addition, the first barrier layer and the second barrier layer may be alternately laminated, or the first barrier layers or the second barrier layers may be adjacent by themselves.

In addition, in one or more embodiments of the invention, the barrier layers may be formed on at least one side of a substrate. For this reason, the gas barrier film in accordance with one or more embodiments of the invention includes both of, the shape of forming the barrier layers on one side of the substrate or the shape of forming the barrier layers on both sides of the substrate.

[ Substrate]

The substrate in accordance with one or more embodiments of the invention is not particularly limited as long as it is a long supporting body, and can maintain barrier layers.

As a substrate, generally, a plastic film or sheet is used, but the film or sheet that is constituted of a colorless and transparent resin is used. A material, thickness, and the like of the plastic film used are not particularly limited, as long as they can maintain barrier layers, a hard coat layer, and the like. According to the use objects, the plastic film may be properly selected. As the plastic film, in detail, there may be a thermoplastic resin such as a polyester resin, a methacrylic resin, a methacrylic acid-maleic acid copolymer, a polystyrene resin, a transparent fluororesin, polyimide, a fluorinated polyimide resin, a polyamide resin, a polyamide imide resin, a polyetherimide resin, a cellulose acylate resin, a polyurethane resin, a polyetheretherketone resin, a polycarbonate resin, an alicyclic polyolefin resin, a polyarylate resin, a polyether sulfone resin, a polysulfone resin, a cycloolefin copolymer, a fluorene ring-converted polycarbonate resin, an alicyclic-converted polycarbonate resin, a fluorene ring-converted polyester resin, and an acryloyl compound.

These substrates may be used singly, or in combination of two or more types thereof.

The thickness of the substrate that is used for the gas barrier film in accordance with one or more embodiments of the invention is properly selected according to the use, and thus, is not particularly limited. However, the thickness may be 5 to 500 μm, or, 25 to 250 μm.

[Smoothing Layer (Basal Layer and Primer Layer)]

The gas barrier film in accordance with one or more embodiments of the invention may have a smoothing layer (basal layer and primer layer) on the side of a substrate having barrier layers, and between the substrate and the barrier layer. The smoothing layer is installed in order to perform the planarization of a rough side of a substrate with projections or the planarization of a substrate by filling the concavo-convex parts and pinholes produced on a barrier layer with the projections present on the substrate. The smoothing layer may be formed with any kinds of materials, or includes a carbon-containing polymer, or is constituted of a carbon-containing polymer. In other words, the gas barrier film in accordance with one or more embodiments of the invention further includes the smoothing layer including a carbon-containing polymer between a substrate and a barrier layer.

In addition, the smoothing layer may include a carbon-containing polymer, and a curable resin. The curable resin is not particularly limited, and there may be an active energy ray-curable resin obtained by irradiating an active energy ray-curable material with active energy ray such as UV ray, and then, curing the material, or a thermosetting resin obtained by heating a thermosetting material, and then, curing the material. The curable resin may be used singly, or in combination of two or more types thereof.

Examples of the active energy ray-curable material that is used for forming a smoothing layer may include an acrylate compound-containing composition, the composition including an acrylate compound and thiol group-containing mercapto compound, the composition including multifunctional acrylate monomers such as epoxy acrylate, urethane acrylate, polyester acrylate, polyether acrylate, polyethylene glycol acrylate, and glycerol methacrylate, and the like. In detail, UV curable organic/inorganic hybrid hard coat material OPSTAR (Registered Trademark) series (the compounds that are constituted of binding the silica particles with an organic compound having a polymeric unsaturated group) manufactured by JSR Corporation may be used. In addition, any mixture of the above-described compositions may be used, and it is not particularly limited as long as it is an active energy ray-curable material including the reactive monomer having one or more photo-polymeric unsaturated bonds in the molecule.

In detail, as the thermosetting material, there may be Tutto prom series (organic polysilazane) manufactured by Clariant. Co., Ltd., SP COAT heat resistance clear coating materials manufactured by Ceramic Coat Co., Ltd., Nano hybrid silicone manufactured by ADEKA CORPORATION, UNIDIC (Registered Trademark) V-8000 series and EPICLON (Registered Trademark) EXA-4710 (Super high heat-resistant epoxy resin) manufactured by DIC Corporation, Silicon resin X-12-2400 (Trade Name) manufactured by Shin-Etsu Chemical Co., Ltd., Inorganic•Organic nanocomposite material SSG coat manufactured by Nitto Boseki Co., Ltd., thermosetting urethane resin, phenol resin, urea melamine resin, epoxy resin, unsaturated polyester resin, silicon resin, polyamideamine epichlorohydrin resin, which are constituted of acrylic polyol and isocyanate prepolymer, and the like.

A method for forming a smoothing layer is not particularly limited, and there may be a method for forming a coating film, which includes forming the coating film by applying the coating solution including curable materials with a wet-coating method such as a spin coating method, a spray method, a blade coating method, a dip method, and a gravure printing method, or a dry coating method such as a vapor deposition method, and then, curing the coating film by irritating with active energy ray such as visible ray, infrared ray, UV ray, X-ray, α-ray, β-ray, γ-ray, and electron ray and/or heating.

The smoothness of a smoothing layer is a value represented by the surface roughness defined in JIS B 0601: 2001, and the maximum cross-sectional height Rt (p) thereof is 10 nm or more and/or 30 nm or less.

The surface roughness is calculated from the cross-sectional curve of the unevenness that is continuously measured with a detector having the sensing pin of a tiny tip radius in AFM (atomic force microscope), and the section is measured several times in the measuring direction of a dozen μm by the sensing pin of a tiny tip radius, and is the roughness concerning a fine concavo-convex amplitude.

The thickness of the smoothing layer is not particularly limited, but may be in the range of 0.1 to 10 μm.

[Anchor Coat Layer]

The surface of the substrate in accordance with one or more embodiments of the invention may include an anchor coat layer as an easily-adhesive layer for improving adhesion (coherency). As the anchor coat material that is used for the anchor coat layer, one or two or more of a polyester resin, an isocyanate resin, a urethane resin, an acrylic resin, an ethylene-vinyl alcohol resin, a vinyl-converted resin, an epoxy resin, a converted styrene resin, a converted silicon resin, and an alkyl titanate may be used. As the anchor coat material, the materials on the market may be used. In detail, a siloxane-based UV curable polymer solution (manufactured by Shin-Etsu Chemical Co., Ltd, 3% isopropyl alcohol solution of “X-12-2400”) may be used.

In addition, the thickness of the anchor coat layer is not particularly limited, but may be about 0.5 to 10.0 μm.

[Bleed-Out Prevention Layer]

For the substrate with a smoothing layer, the surface of the substrate may be contaminated by shifting non-reacted oligomers and the like to the surface of the substrate during heating. The bleed-out prevention layer has the function of inhibiting the contamination of the surface of the substrate. In the case of having the bleed-out prevention layer, the bleed-out prevention layer is installed on the opposite side of the smoothing layer of the substrate with the smoothing layer.

When the bleed-out prevention layer has the above-described function, the layer may be constituted in the same constitution of the smoothing layer. In other words, the bleed-out prevention layer may be formed by applying a photosensitive resin composition, and then, curing the composition.

When one controlling layer selected from the group consisting of the above-described anchor coat layer, smoothing layer, and bleed-out layer is formed on the substrate, the total film thickness of the substrate and controlling layer may be 5 to 500 μm or 25 to 250 μm.

In addition, an intermediate layer may be formed between the first inorganic layer and the second inorganic layer.

The intermediate layer may be formed for strengthening the gas barrier properties of the first barrier layer, strengthening the adhesion between the first barrier layer and second barrier layer, and the like. At this time, the intermediate layer is formed within the range that does not hinder the effect of embodiments of the invention.

The intermediate layer may be any one of an inorganic layer, an organic layer, and an organic and inorganic hybrid layer, or an inorganic layer.

A material for an inorganic layer is not particularly limited, may be the same material as the first inorganic layer or second inorganic layer, and may be other materials. Examples of the material that is used for the inorganic layer as an intermediate layer may include zirconia, titania, and the like.

As a material for an organic layer, the polymer material prepared by polymerizing crosslinking monomers may be used. The crosslinking monomer is not particularly limited, and there may be an acryloyl group, a methacryloyl group, an oxirane group, and the like.

As the material for an organic and inorganic hybrid layer, silsesquioxane may be used.

The thickness of the intermediate layer may be 0.05 to 10 nm, or 0.1 to 5 nm. However, when the same material as the first inorganic layer or second inorganic layer is used as the material for the intermediate layer, in the case when the thickness of the intermediate layer exceeds 10 nm, the intermediate layer belongs to the first inorganic layer or second inorganic layer.

[First Barrier Layer (First Inorganic Layer)]

The first inorganic layer is formed by a vapor deposition method, but may be formed by a chemical vapor deposition method (CVD method) or a physical vapor deposition method (PVD method). Here, the first inorganic layer may include at least one type of oxide, nitride, acid nitride, or acid carbide of at least one selected from the group consisting of silicon, aluminum, and titanium. In detail, as oxide, nitride, acid nitride, acid carbide, or acid nitride carbide of at least one selected from the group consisting of silicon, aluminum, and titanium, there may be silicon oxide (SiO₂), silicon nitride, acid silicon nitride (SiON), silicon oxycarbide (SiOC), silicon carbide, aluminum oxide, titanium oxide, and complexes thereof such as aluminum silicate. Among them, acid silicon nitride (SiON), silicon nitride (SiN), hydrogenated silicon nitride (SiNH), silicon oxycarbide (SiOC), silicon oxide (SiO₂), aluminum silicate (SiAlO), and silicon oxynitride-carbide (SiONC) may be used. These components may include other elements as an auxiliary component.

The first inorganic layer has the above-described compounds, and gas barrier properties. Here, for the gas barrier properties of the first inorganic layer, when being calculated in the laminate formed with the first inorganic layer on a substrate, the amount of moisture permeation measured by the method described in Examples to be described below may be 0.1 g/(m²·24 h) or less, or 0.01 g/(m²·24 h) or less.

A physical vapor deposition method (PVD method) is a method of depositing a material, for example, a thin film such as a carbon film, by a physical way, on the surface of a material in a vapor-phase, and for example, there may be a sputtering method (DC sputtering, RF sputtering, ion beam sputtering, magnetron sputtering, and the like), a vacuum vapor deposition method, an ion plating method, and the like.

As a raw material compound, a silicon compound, a titanium compound, and an aluminum compound are used. As these compounds, the conventionally known compounds may be used.

In addition, as a decomposition gas to be used at the time of obtaining an inorganic compound by decomposing an raw material gas including a metal, there may be a hydrogen gas, a methane gas, an acetylene gas, a carbon monoxide gas, a carbon dioxide gas, a nitrogen gas, an ammonia gas, a nitrous oxide gas, a nitric oxide gas, a nitrogen dioxide gas, an oxygen gas, vapor, and the like. In addition, the decomposition gas may be mixed with an inert gas such as an argon gas, and a helium gas.

The thickness of the first inorganic layer in accordance with one or more embodiments of the invention may be 10 to 1000 nm, or 150 to 200 nm. When the thickness thereof is in the above-described range, it is difficult to be influenced by the defect part or the part that has low density between the crystals, and it is possible to obtain high gas barrier properties. In addition, in the case of being converted, it is possible to reduce the breaking of inorganic layer.

Hereinafter, among the CVD methods, an embodiment of a plasma CVD method will be described in detail.

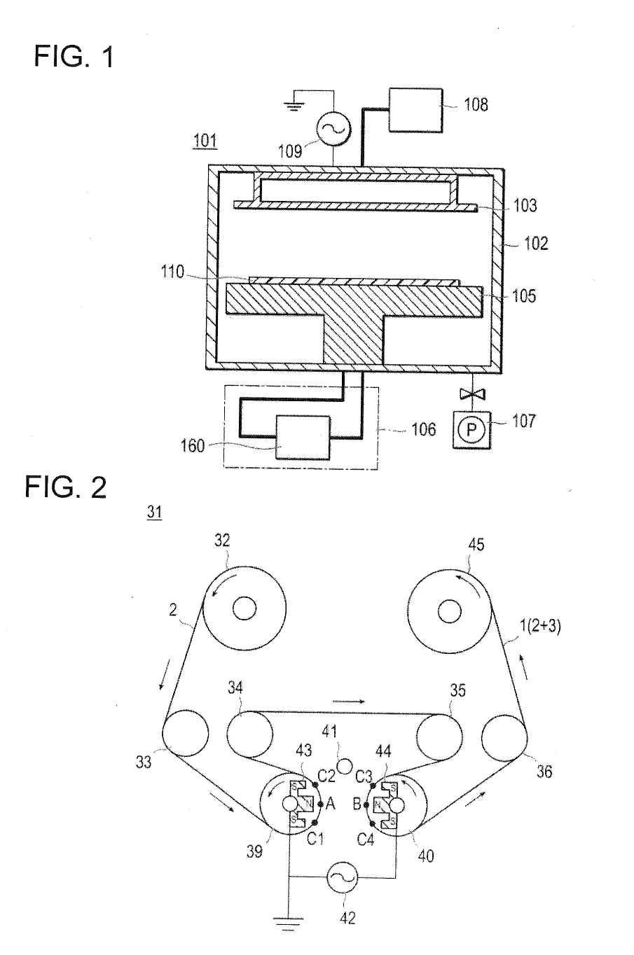

FIG. 1 is a schematic diagram illustrating an example of vacuum plasma CVD device used for forming the first inorganic layer according to embodiments of the invention.

In FIG. 1, a vacuum plasma CVD device 101 has a vacuum chamber 102, and a susceptor 105 is arranged in the internal bottom side of the vacuum chamber 102. In addition, a cathode electrode 103 is arranged at the position opposing to the susceptor 105 in the internal ceiling side of the vacuum chamber 102. A heating medium circulating system 106, a vacuum exhaust system 107, a gas introducing system 108, and a high frequency power supply 109 are arranged in the outside of the vacuum chamber 102. A heating medium is arranged in the heating medium circulating system 106. In the heating medium circulating system 106, a heating-cooling device 160 having a pump for moving a heating medium, a heater for heating a heating medium, a cooler for cooling a heating medium, a temperature sensor for measuring the temperature of a heating medium, and a storage unit for memorizing a setting temperature of a heating medium is installed. The detailed explanation of the vacuum plasma CVD device illustrated in FIG. 1 may refer to WO 12/014653 A.

(First Inorganic Layer Embodiments)

In addition, as an embodiment of the first inorganic layer in accordance with one or more embodiments of the invention, the first inorganic layer includes carbon, silicon, and oxygen as a constituent element. There is the first inorganic layer that satisfies the following requirements (i) and (ii).

(i) For a silicon distribution curve exhibiting the relationship between the distance L from the surface of the first inorganic layer for the film thickness direction of the first inorganic layer and the ratio of the amount of silicon atom (the atom ratio of silicon) with respect to the total amount of a silicon atom, an oxygen atom, and a carbon atom, an oxygen distribution curve exhibiting the relationship between the L and the ratio of the amount of oxygen atom (the atom ratio of oxygen) with respect to the total amount of a silicon atom, an oxygen atom, and a carbon atom, and a carbon distribution curve exhibiting the relationship between the L and the ratio of the amount of carbon atom (the atom ratio of carbon) with respect to the total amount of a silicon atom, an oxygen atom, and a carbon atom, the carbon distribution curve has at least two extreme values; and

(ii) For the carbon distribution curve, the absolute value of the difference between maximum value and minimum value of the ratio of carbon atom is 3 at % or more.

By having such a composition, embodiments of the invention provide both gas barrier properties and flexibility highly.

In addition, in the area of 90% or more of the thickness of total layers of the first inorganic layers, the average atom ratio of each of the atoms with respect to the total amount (100 at %) of a silicon atom, an oxygen atom, and a carbon atom has the large/small relationship of the order represented by the following Equation (A) or (B).

(Average atom ratio of carbon)<(Average atom ratio of silicon)<(Average atom ratio of oxygen) Equation (A)

(Average atom ratio of oxygen)<(Average atom ratio of silicon)<(Average atom ratio of carbon) Equation (B)

When satisfying the above relationship, the flexure resistance is further improved.

Hereinafter, the another embodiment will be described.

(i) For a silicon distribution curve exhibiting the relationship between the distance L from the surface of the first inorganic layer for the film thickness direction of the first inorganic layer and the ratio of the amount of silicon atom (the atom ratio of silicon) with respect to the total amount of a silicon atom, an oxygen atom, and a carbon atom, an oxygen distribution curve exhibiting the relationship between the L and the ratio of the amount of oxygen atom (the atom ratio of oxygen) with respect to the total amount of a silicon atom, an oxygen atom, and a carbon atom, and a carbon distribution curve exhibiting the relationship between the L and the ratio of the amount of carbon atom (the atom ratio of carbon) with respect to the total amount of a silicon atom, an oxygen atom, and a carbon atom, the carbon distribution curve has at least two extreme values. For the first inorganic layer, the carbon distribution curve has at least three extreme values, or has more, at least four extreme values, and may have five or more extreme values. When the carbon distribution curve has at least two extreme values, the carbo atom ratio has concentration gradient and is continuously changed, thereby increasing gas barrier performance at the time of flexure. In addition, the upper limit of the extreme value of the carbon distribution curve is not particularly limited, but for example, 30 or less, or 25 or less. The number of extreme values may be caused even by the film thickness of the barrier layer, and thus, it cannot be specified in a word.

Here, in the case of having at least three extreme values, the absolute values of the difference between one extreme value and the extreme value being adjacent thereto of the carbon distribution curve and the distance L from the surface of the first inorganic layer for the film thickness direction of the first inorganic layer (hereinafter, simply called “the distance between the extreme values”) are together 200 nm or less, 100 nm or less, or 75 nm or less. When it is the above-described distance of the distance between the extreme values, the regions (maximum value) having many atom ratio of carbon in the first inorganic layer exist in the proper period, thereby imparting proper flexibility to the first inorganic layer. Therefore, it is possible to more effectively suppress•prevent the generation of cracks at the time of the flexure of the gas barrier film. In addition, the extreme value in the present specification indicates the maximum value or minimum value of the atom ratio of the element with respect to the distance L from the surface of the first inorganic layer for the film thickness direction of the first inorganic layer. In addition, in the present specification, the maximum value indicates the point, in which the value of the atom ratio of the element (oxygen, silicon, or carbon) changes from the increase to the decrease when the distance from the surface of the first inorganic layer is changed. In addition, the maximum value indicates the point, in which as compared with the value of the atom ratio of the element at the above-described point, the value of the atom ratio of the element at the position, in which the distance from the surface of the first inorganic layer for the film thickness direction of the first inorganic layer at the above-described point is changed in the range of 4 to 20 nm, is decreased by 3 at % or more. In other words, when being changed in the range of 4 to 20 nm, the value of the atom ratio of the element is decreased by 3 at % or more in some ranges. This is changed by the film thickness of the first inorganic layer. For example, when the film thickness of the first inorganic layer is 300 nm, the point in which the value of the atom ratio of the element at the position, in which the distance from the surface of the first inorganic layer for the film thickness direction of the first inorganic layer is changed by 20 nm, is decreased by 3 at % or more. In addition, in the present specification, the minimum value indicates the point, in which when the distance from the surface of the first inorganic layer is changed, the value of the atom ratio of the element (oxygen, silicon, or carbon) is changed from the decrease to the increase, and also, the point, in which as compared with the value of the atom ratio of the element at the above-described point, the value of the atom ratio of the element at the position, in which the distance from the surface of the first inorganic layer for the film thickness direction of the first inorganic layer at the point is further changed in the range of 4 to 20 nm, is increased by 3 at % or more. In other words, when being changed in the range of 4 to 20 nm, the value of the atom ratio of the element is increased by 3 at % or more in some ranges. Here, in the case of having at least three extreme values, the lower limit of the distance between the extreme values is not particularly limited, because as the distance between the extreme values decreases, the improvement effect of suppressing/preventing the generation of cracks at the time of the flexure of the gas barrier film is high.

In addition, the first inorganic layer has 3 at % or more of the absolute value of the difference between the maximum value and minimum value of the atom ratio of carbon in the carbon distribution curve (ii), 5 at % or more, or 7 at % or more. When the absolute value of the difference between the maximum value and minimum value of the atom ratio of carbon in the carbon distribution curve is 3 at % or more, the gas barrier performance at the time of flexure is increased. In addition, in the present specification, the “maximum value” indicates the atom ratio of each of the elements to be maximum value in the distribution curve of each of the elements, and the highest values among the maximum values. Similarly, in the present specification, the “minimum value” indicates the atom ratio of each of the elements to be minimum value in the distribution curve of each of the elements, and the lowest value among the minimum values.

In addition, in the area of 90% or more (upper limit: 100%) of the film thickness of the first inorganic layer, the order of (atom ratio of oxygen), (atom ratio of silicon), and (atom ratio of carbon) is increased (atom ratio: O>Si>C). By being such a condition, the gas barrier properties and flexibility of the obtained gas barrier film become sufficient. Here, in the carbon distribution curve, the relationship of (atom ratio of oxygen), (atom ratio of silicon), and (atom ratio of carbon) is satisfied in the area of at least 90% or more (upper limit: 100%) of the film thickness of the barrier layer, or satisfied in the area of at least 93% or more (upper limit: 100%). Here, as the meaning of at least 90% or more of the film thickness of the barrier layer, the above-relationship may be satisfied in the part of only 90% or more, but being not continuous in the barrier layer.

The silicon distribution curve, the oxygen distribution curve, the carbon distribution curve, and the oxygen carbon distribution curve may be prepared by a so-called XPS depth profile measurement that performs the surface compositions analysis one by one while the insides of the samples are exposed by using both of the X-ray photoelectron spectroscopy (XPS) measurement and the ion sputtering of rare gas such as argon. The distribution curve obtained by such an XPS depth profile measurement may be prepared by using the atom ratios of respective elements (unit: at %) as a vertical axis and an etching time (sputtering time) as a horizontal axis. In addition, in the distribution curve of the element using an etching time as a horizontal axis, since the etching time almost is generally related to the distance L from the surface of the first inorganic layer for the film thickness direction of the first inorganic layer in the film thickness direction, the distance from the surface of the first inorganic layer, which is calculated from the relationship between the etching rate and etching time that are used for measuring an XPS depth profile measurement, may be used as “the distance from the surface of the first inorganic layer for the film thickness direction of the first inorganic layer.” The silicon distribution curve, the oxygen distribution curve, the carbon distribution curve, and the oxygen carbon distribution curve are prepared under the following measurement conditions.

(Measurement Conditions)

Etching ion type: Argon (Ar⁺);

Etching rate (SiO₂ thermal oxide film conversion value): 0.05 nm/sec;

Etching interval (SiO₂ conversion value): 10 nm;

X-ray photoelectron spectrometer: manufactured by Thermo Fisher Scientific Co., Ltd., Model Name “VG Theta Probe”;

Irradiating X-rays: single crystal spectroscopy AlKα

X-ray spot and size thereof: Ellipse of 800×400 μm

From the viewpoint of forming the first inorganic layer having the whole uniform film sides and excellent gas barrier properties, the first inorganic layer be substantially uniform in the film side direction (the direction that is parallel on the surface of the first inorganic layer). Here, the meaning of the first inorganic layer being substantially uniform in the film side direction indicates that when preparing the oxygen distribution curve, the carbon distribution curve, and the oxygen carbon distribution curve for the measurement places of any two places on the film side of the first inorganic layer by an XPS depth profile measurement, the numbers of the extreme values of the carbon distribution curve obtained in the measurement places of any two places are the same, and the absolute values of the differences between the maximum values and minimum values of the atom ratios of carbon in the respective carbon distribution curves are the same each other or are the differences of 5 at % or less.

In addition the carbon distribution curve is substantially continuous. Here, the meaning of the substantially continuous carbon distribution curve means that the carbon distribution curve does not include the part, in which the atom ratio of carbon is discontinuously changed. In detail, it indicates that the relationship between the distance (x, unit: nm) from the surface of the first inorganic layer for the film thickness direction of at least one layer among the first inorganic layers, which is calculated from the etching rate and etching time, and the atom ratio of carbon (C, unit: at %) satisfies the conditions represented by the following Equation (1).

[Equation 1]

(dC/dx)≦0.5 (1)

In addition, when the first inorganic layer has a sub layer, a plurality of sub layers that satisfy all of the above-described conditions (i) and (ii) may be laminated to form the first inorganic layer. When having two or more sub layers, the materials for the plurality of sub layers may be the same or may be different from each other.

As an embodiment of the first inorganic layer, the layer that satisfies the requirements (i) and (ii) is the layer formed by a plasma CVD (PECVD) method, or the layer formed by a plasma CVD method including arranging a substrate on a pair of film-forming rollers and then discharging between a pair of film-forming rollers to produce plasma. In addition, the plasma CVD method may be a plasma CVD method in a penning discharging plasma way.

When plasma is produced by the plasma CVD method, generate plasma discharging in the space between a plurality of film-forming rollers, or generate plasma by using a pair of film-forming rollers, arranging the substrates for a pair of film-forming rollers, respectively, and discharging between a pair of film-forming rollers. In this way, by using a pair of film-forming rollers, arranging a substrate on a pair of film-forming rollers, and then, discharging between a pair of film-forming rollers, while a film is formed on the surface part of the substrate that is present on the one of the film-forming rollers during film-forming, it is also possible to form a film on the surface part of the substrate that is present on other one of the film-forming rollers at the same time, thereby effectively forming a thin film. In addition, as compared with the plasma CVD method without using a general roller, it is possible to make the film-forming rate double, and also, it is possible to form the film having almost same structure. Therefore, it is possible to increase the extreme value in the carbon distribution curve by at least two times, and thus, it is possible to effectively form the layer that satisfies all of the conditions (i) and (ii).

In addition, when discharging between a pair of film-forming rollers in this way, reverse the polarities of the pair of film-forming rollers in turn. In addition, a film-forming gas used for this plasma CVD method includes an organic silicon compound and oxygen, and the content of oxygen in the film-forming gas is less than theoretical amount of oxygen that is required for completely oxidizing the total amount of the organic silicon compound in the film-forming gas. In addition, the gas barrier film in accordance with one or more embodiments of the invention is the layer, in which the barrier layer is formed by a continuous film-forming process.

In addition, from the viewpoint of productivity, form the first inorganic layer on the surface of the substrate in a roll-to-roll way. In addition, a device that may be used when preparing the first inorganic layer by such a plasma CVD method is not particularly limited, but the device having a pair of film-forming rollers and a plasma power supply, which is constituted of discharging between the pair of film-forming rollers. For example, when using the producing device illustrated in FIG. 2, it is possible to manufacture it in a roll-to-roll way while using the plasma CVD method.

Hereinafter, referring to FIG. 2, the method for forming a first inorganic layer will be described in more detail. In addition, FIG. 2 is a schematic diagram illustrating an example of the producing device that may be suitably used for forming a first inorganic layer. In addition, among the following explanation and drawings, the same or corresponding elements will be represented by the same marks, and the overlap explanations will not be provided.

A producing device 31 illustrated in FIG. 2 includes a delivery roller 32, conveying rollers 33, 34, 35, and 36, film-forming rollers 39 and 40, a gas supply tube 41, a power supply for plasma generation 42, magnetic field generating apparatuses 43 and 44 installed in the film-forming rollers 39 and 40, and a winding roller 45. In addition, in such a producing device, at least film-forming rollers 39 and 40, a gas supply tube 41, a power supply for plasma generation 42, and magnetic field generating apparatuses 43 and 44 are arranged in a vacuum chamber that is not illustrated. In addition, in such a producing device 31, the vacuum chamber is connected to a vacuum pump that is not illustrated, and thus, it is possible to properly control the pressure in the vacuum chamber by the vacuum pump. The detailed explanation about the device may refer to JP 2011-73430 A that is conventionally known, for example.

As described above, as an aspect of the present embodiment, the first inorganic layer is formed by a plasma CVD method using a plasma CVD device (roll-to-roll way) having an opposing roll electrode illustrated in FIG. 2. This is because when it is mass-formed using a plasma CVD device (roll-to-roll way) having an opposing roll electrode, flexibility is excellent, and thus it is possible to effectively form the first inorganic layer having both of the mechanical strength, especially, durability at the time of the conveyance with the roll-to-roll, and barrier properties. Such a producing device is excellent from the viewpoint of easily mass-forming the gas barrier film, at a low cost, which requires durability to the temperature change and is used for a solar cell, electronic parts, and the like.

[Second Barrier Layer (Second Inorganic Layer)]

The second barrier layer is formed by applying the coating solution including a polysilazane compound and nanoparticles (hereinafter, also called “nanoparticles-containing and polysilazane-containing coating solution”) on a substrate and then irradiating the obtained coating film with vacuum UV ray of a wavelength of 200 nm or less (Process 1).

(Nanoparticles-Containing and Polysilazane-Containing Coating Solution)

The nanoparticles-containing and polysilazane-containing coating solution includes a polysilazane compound and nanoparticles.

Polysilazane Compound

The polysilazane compound is a polymer having the bonds such as Si—N, Si—H, and N—H in the structure thereof, and functions as an inorganic precursor of SiO₂, Si₃N₄, and their intermediate solid solutions, SiOₓN_{y}.

The polysilazane compound is not particularly limited, but considering the conversion treatment to be described below, the compound may become ceramic at a relatively low temperature and may be converted into silica. For example, the compound may have a main skeleton made of the unit represented by the following General Formula (1) disclosed in JP 8-112879 A.

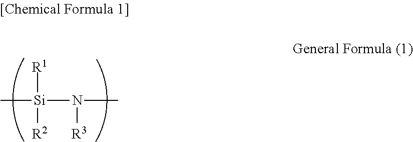

In the above General Formula (1), R¹, R², and R³ represent a hydrogen atom, and a substituted and unsubstituted alkyl group, aryl group, vinyl group, or (trialkoxysilyl)alkyl group. At this time, R¹, R², and R³ are each the same or different from each other. Here, the alkyl group may be a linear, branched, or cyclic alkyl group having 1 to 8 carbon atoms. In more detail, there may be a methyl group, an ethyl group, a n-propyl group, an isopropyl group, a n-butyl group, an isobutyl group, a sec-butyl group, a tert-butyl group, a n-pentyl group, an isopentyl group, a neopentyl group, a n-hexyl group, a n-heptyl group, a n-octyl group, a 2-ethylhexyl group, a cyclopropyl group, a cyclopentyl group, a cyclohexyl group, and the like. In addition, the aryl group may be an aryl group having 6 to 30 carbon atoms. In more detail, there may be a non-condensed hydrocarbon group such as a phenyl group, a biphenyl group, and a terphenyl group; a condensed polycyclic hydrocarbon group such as a pentalenyl group, an indenyl group, a naphthyl group, an azulenyl group, a heptalenyl group, a biphenylenyl group, a fluorenyl group, an acenaphthylenyl group, a playadenyl group, an acenaphthenyl group, a phenalenyl group, a phenanthryl group, an anthryl group, a fluoranthenyl group, an acephenanthrylenyl group, an aceanthrylenyl group, a triphenylenyl group, a pyrenyl group, a chrysenyl group, and a naphthacenyl group. The (trialkoxysilyl)alkyl group may be an alkyl group having 1 to 8 carbon atoms, which has a silyl group substituted with an alkoxy group having 1 to 8 carbon atoms. In more detail, there may be a 3-(triethoxysilyl)propyl group and a 3-(trimethylsilyl)propyl group. A substituent that is present in the above-described R¹ to R³ depending on cases is not particularly limited, and examples thereof include an alkyl group, a halogen atom, a hydroxyl group (—OH), a mercapto group (—SH), a cyano group (—CN), a sulfo group (—SO₃H), a carboxyl group (—COOH), a nitro group (—NO₂), and the like. In addition, the substituent that is present depending on cases may be never the same as R¹ to R³ to be substituted. For example, when R¹, R², and R³ are alkyl groups, there is no case of further substitution with an alkyl group. Among the substituents, R¹, R², and R³, a hydrogen atom, a methyl group, an ethyl group, a propyl group, an isopropyl group, a butyl group, an isobutyl group, a tert-butyl group, a phenyl group, a vinyl group, a 3-(triethoxysilyl)propyl group, or a 3-(trimethoxysilylpropyl) group. Perhydropolysilazane (PHPS) in which all R¹, R², and R³ are hydrogen atoms. The barrier layer (gas barrier layer) formed with this polysilazane exhibits high compactness.

Perhydropolysilazane is presumed to have a structure with a linear structure and a cyclic structure centering on the 6 and 8-membered rings. The molecular weight thereof is about 600 to 2,000 (polystyrene conversion) as a number average molecular weight (Mn), and may be a liquid or solid substance (different depending on the molecular weight thereof). As the perhydropolysilazane, an article on the market may be used, and as the article on the market, there may be AQUAMICA NN120, NN120-10, NN120-20, NN110, NAX120, NAX120-20, NAX110, NL120A, NL120-20, NL110A, NL150A, NP110, NP140 (all, manufactured by AZ Electronic Materials Co., Ltd.), and the like.

The content of the polysilazane compound in the nanoparticles-containing and polysilazane-containing coating solution 0.2 to 35% by mass with respect to the total amount of the nanoparticles-containing and polysilazane-containing coating solution, but depends on the film thickness of the barrier layer, the pot life of the coating solution, or the like.

Nanoparticles

Nanoparticle mean a particle having the average particle diameter of 1 nm or more and 1000 nm or less as a spherical equivalent diameter.

Nanoparticle in accordance with one or more embodiments of the invention is at least one type of nanoparticle among metal oxides and metal nitrides. The metal of the nanoparticle in accordance with one or more embodiments of the invention is not particularly limited, but is selected from the oxides and nitrides including at least one element selected from the group consisting of Si, Ti, Al, Zr, Zn, Ba, Sr, Ca, Mg, V, Cr, Mo, Li, and Mn.

The size of particle is 1 to 120 nm as a spherical equivalent diameter, or 5 to 100 nm. When the particle size of water absorbent is 1 to 120 nm as a spherical equivalent diameter, it is possible to maintain transparency and also the amount of water absorption per unit mass increases. Considering the further improvement of gas barrier properties (for example, vapor barrier properties) or durability, the spherical equivalent diameter of nanoparticle is 8 to 90 nm, or 10 to 70 nm.

In addition, “the spherical equivalent diameter” that is described here means the spherical diameter when the particle size is converted into the globe, in which the volume thereof is the same as the particle. Measuring with a concentrated system-particle size analyzer “FPAR-1000” manufactured by Otsuka Electronics Co., Ltd., dispersibility is measured and then average volume is obtained, and then, is converted into a spherical equivalent diameter.

The nanoparticle in accordance with one or more embodiments of the invention may be properly selected from the compounds having a water absorption function centering on an alkali earth metal. For example, the nanoparticle including at least one type selected from the group consisting of Si₃N₄, TiO₂, Al₂O₃, ZrO₂, ZnO, BaO, SrO, CaO, MgO, VO, CrO, MoO₂, and LiMnO₂ is included in the nanoparticle. A boehmite type of aluminum oxide is particularly useful. In addition, the nanoparticle may be selected from the metal elements such as Ti, Mg, Ba, and Ca. The nanoparticle may be a globe platelet or other shapes. For the platelet or other relatively flat particles (high aspect ratio), the partial or completed orientation of the relatively flat surface of the particularly useful particle may be parallel with the surface of a substrate. The nanoparticle may be included in the coating mixed solution in the amount of 3 to 90 percentages, 30 to 75 percentages, or 40 to 70 percentages with respect to the solid content of extreme curing coating. The particles may be distributed in a coating mixed solution of a polar solvent, for example, DMF, DMSO, and water. Before the distribution of nanoparticles, the surfaces thereof may be converted. A silane-converted particle, particularly, an epoxysilane-converted particle may be used in an embodiment of the invention. A surfactant may be included for preparing the dispersion that is stable for nanoparticles. The surfactant includes a nitric acid, a formic acid, a citric acid, ammonium citrate, ammonium polymethacrylate, and silane. The polysilazane-containing coating solution is prepared, and nanoparticles may be added to the curable component that is the dispersion in a solvent.

The content of nanoparticles in the nanoparticles-containing and polysilazane-containing coating solution is 0.01 to 0.5% by mass with respect to the total amount of the nanoparticles-containing and polysilazane-containing coating solution, but depends on the film thickness of the barrier layer or the pot life of the coating solution.

In addition, the mixing ratio of polysilazane compound and nanoparticles is not particularly limited. Considering the effect on improving the gas barrier properties (especially, gas barrier properties under a high temperature and high humidity) and the coherency of barrier layer, the nanoparticles is mixed in the ratio of 0.5 to 20% by mass or 1 to 10% by mass, with respect to 100% by mass of the polysilazane compound. When using such a mixing ratio, the nanoparticles are properly interacted with the Si—N bond of the polysilazane compound, and thus, it is possible to further improve the strength of the second inorganic layer under a wet-heat environment. In addition, since the nanoparticles are also properly interacted with the first inorganic layer, it is possible to further improve the coherency between the first and second inorganic layers.

The nanoparticles-containing and polysilazane-containing coating solution may further include an amine catalyst, a metal, and a solvent.

Amine Catalyst and Metal

The amine catalyst and metal may promote the conversion of the polysilazane compound into a silicon oxide compound.

The amine catalyst that may be used is not particularly limited, but there may be N,N-dimethyl ethanolamine, N,N-diethylethanolamine, triethanolamine, triethylamine, 3-morpholinopropylamine, N,N,N′,N′-tetramethyl-1,3-diaminopropane, N,N,N′,N′-tetramethyl-1,6-diaminohexane.

In addition, the metal that may be used is not particularly limited, but there may be a platinum compound such as platinum acetylacetonate, a palladium compound such as palladium propionate, a rhodium compound such as rhodium acetylacetonate, and the like.

The amine catalyst and metal are included in the amount of 0.05 to 10% by mass, 0.1 to 5% by mass, or 0.5 to 2% by mass, with respect to the polysilazane compound. When the added amount of catalyst is in the above-described range, it is possible to prevent the excessive formation of silanol, the decrease in a film density, and the increase in a film defect, which are caused by the rapid progression of a reaction.

Solvent

The solvent that may be included in the nanoparticles-containing and polysilazane-containing coating solution is not particularly limited, as long as it is not reacted with a polysilazane compound and nanoparticles, and the known solvents may be used. In detail, as a solvent, there may be hydrocarbon-based solvents such as aliphatic hydrocarbon, alicyclic hydrocarbon, aromatic hydrocarbon, and halogenated hydrocarbon solvents; and ether-based solvents such as aliphatic ether and alicyclic ether solvents. In more detail, as the hydrocarbon solvent, there may be pentane, 2,2,4-trimethylpentane, hexane, cyclohexane, toluene, xylene, solvesso, turpentine, methylene dichloride, trichloroethane, and the like. In addition, as the ether-based solvent, there may be dibutyl ether, dioxane, tetrahydrofuran, and the like. These solvents may be used singly, or in combination of two or more types thereof. These solvents may be properly selected according to the purposes, considering the solubility of polysilazane compound and the evaporation rate of a solvent.

(Formation of Polysilazane Coating Film)

The polysilazane-containing coating solution including metal oxide nanoparticles or metal nitride nanoparticles is applied on the first inorganic layer, and then, dried to form a polysilazane coating film.

As a method for forming a polysilazane coating film by applying the polysilazane-containing coating solution, a proper wet coating method that is conventionally known may be used. Specific examples thereof may include a spin coating method, a roll coating method, a flow coating method, an inkjet method, a spray coating method, a printing method, a dip-coating method, a flexible-film-forming method, a bar-coating method, a gravure printing method, and the like.

The coating thickness may be properly set according to the purposes. For example, as the coating thickness, the thickness after drying is 10 to 1000 nm, 20 to 600 nm, or 40 to 400 nm. When the thickness of film is 10 nm or more, it is possible to obtain sufficient barrier properties, and when it is 1000 nm or less, it is possible to obtain stable coating properties at the time of forming a layer, and also, to implement high light permeability.

After applying the coating solution, coating film is dried. By drying the coating film, the organic solvent included in the coating film may be removed.

The temperature for drying the coating film is 20 to 200° C. or 50 to 120° C., even though it is depended on the substrate to be applied. When the heat treatment is performed in such a temperature range, it is from the viewpoint of preventing the deformation of a plastic film or the deterioration of strength thereof.

(Conversion Treatment)

The conversion treatment indicates the conversion reaction of a polysilazane compound into silicon oxide, and also, the treatment for forming an inorganic thin film in the level capable of contributing to the general expression of gas barrier properties (vapor permeability of 1×10⁻³ g/m²·day or less) by the gas barrier film in accordance with one or more embodiments of the invention.

Such a conversion treatment may be performed by irradiating with vacuum UV ray (hereinafter, “VUV” or “VUV ray”) having a wavelength of 200 nm or less.

The oxidation reaction by active oxygen or ozone is performed while directly cutting an atomic bond by the function by only a photon called a photon process using VUV ray, and it is possible to form a silicon nitride oxide film or silicon oxide film at a relatively low temperature. In addition, this method is suitable for the preparation in a roll-to-roll way having good productivity.

Irradiation Treatment of Vacuum UV Ray: Excimer Irradiation Treatment

The conversion treatment method is a treatment by the irradiation of vacuum UV ray (Excimer irradiation treatment). For the treatment by the irradiation of vacuum UV ray, the wavelength to be used is necessarily 200 nm or less from the viewpoint of effectively performing the conversion. Therefore, the light energy having 100 to 200 nm that is larger than the binding force between atoms in the polysilazane compound is used, the light energy having the wavelength of 100 to 180 nm is used to perform the oxidation reaction by active oxygen or ozone while directly cutting an atomic bond by the action of only a photon called a photon process, and this method is a method for performing the formation of a silicon oxide film at a relatively low temperature (about 200° C. or less).

The light source of vacuum UV ray is not particularly limited, and the known light sources may be used. For example, there may be a low pressure mercury lamp, an excimer lamp, and the like. Among them, the excimer lamp, especially, a xenon (Xe) excimer lamp is used.

As an excimer ray (vacuum UV ray)-irradiating device, it is possible to use the lamp available on the market (for example, manufactured by Ushio Inc. and manufactured by M. D. COM. Inc.).

The excimer lamp is characterized in that the excimer ray is concentrated to one wavelength, and thus, does not almost emit light, excepting necessary light, thereby exhibiting high efficiency. In addition, since it does not emit extra light, it is possible to maintain the temperature of an object low. In addition, since it does not need the time for starting or re-starting, it is possible to switch on and off, immediately. Especially, the Xe excimer lamp emits vacuum UV ray having the short wavelength of 172 nm as a single wavelength, and thus, exhibits excellent lamp efficiency. The Xe excimer lamp has the short wavelength of 172 nm and high energy, and thus, it is known that the cleavage ability of the bond of organic compound thereof is high.

The irradiation intensity of vacuum UV ray is 1 to 100 kW/cm² or 1 to 10 W/cm², even though it depends on the substrate to be used, and the composition and concentration of the first barrier layer.

The irradiation time of vacuum UV ray is 0.1 seconds to 10 minutes, or 0.5 seconds to 3 minutes, even though it depends on the substrate to be used, and the composition and concentration of the first barrier layer.

The light accumulated amount of vacuum UV ray is not particularly limited, but is 200 to 5000 mJ/cm², or 500 to 3000 mJ/cm². When the light accumulated amount is 200 mJ/cm² or more, it is possible to obtain high barrier properties by performing sufficient conversion. Meanwhile, when the light accumulated amount of vacuum UV ray is 5000 mJ/cm² or less, it is possible to form the barrier layer having high smoothness without deforming a substrate.

In addition, the irradiation temperature of vacuum UV ray depends on the substrate to be applied, and thus, may be properly determined by those in the art. The irradiation temperature of vacuum UV ray is 50 to 200° C., or 80 to 150° C. When the irradiation temperature is in the above-described range, it is difficult to generate the deformation of a substrate and the deterioration of strength, and the properties of a substrate are not damaged.

The reaction at the time of UV irradiation needs oxygen. However, for the vacuum UV ray, because the absorption is generated by oxygen, it is easy to decrease the efficiency in the UV ray irradiation process. Therefore, the irradiation of vacuum UV ray is performed at the state of vapor concentration and oxygen concentration which are as low as possible. In other words, the oxygen concentration at the time of the irradiation of vacuum UV ray is 10 to 20,000 volume ppm (0.001 to 2% by volume), 50 to 10,000 volume ppm, or 100 to 5000 ppm. In addition, the vapor concentration during the conversion process is in the range of 1000 to 4000 volume ppm.

As a gas that is used at the time of the irradiation of vacuum UV ray and satisfies the irradiation atmosphere, a dried inert gas is used, and especially, a dried nitrogen gas. The oxygen concentration may be possible to be controlled by changing the flow ratio after measuring the flow amount of inert gas and oxygen gas to be introduced in the irradiation storage.

The irradiation energy amount of vacuum UV ray on the surface of a coating film is 200 to 10000 mJ/cm², or 500 to 5000 mJ/cm². When it is 200 mJ/cm² or more, it is possible to perform sufficient conversion. When it is 10000 mJ/cm² or less, it is possible to suppress the generation of cracks and the heat deformation of a substrate by excess conversion.

In addition, the vacuum UV ray that is used for the conversion may be generated by the plasma formed by the gas including at least one type of CO, CO₂, and CH₄.

In the coating film to be an object irradiated with UV ray, oxygen and a trace of water may be mixed at the time of applying, and also, in a substrate or adjacent layer, the adsorbed oxygen or adsorbed water may be present. When using the oxygen, even though oxygen is not newly introduced in the irradiation storage, the oxygen source that is required to generate active oxygen or ozone to be conversion-treated may be sufficient. In addition, since the vacuum UV ray of 172 nm like a Xe excimer lamp is absorbed by oxygen, there may be the cases of decreasing the amount of vacuum UV ray to be reached to the coating film. Therefore, at the time of irradiating with vacuum UV ray, the oxygen concentration is set to be low, and thus, the condition, in which the vacuum UV ray is effectively reached to the coating film, is set.

The film thickness, density, and the like of the barrier layer obtained by the above-described conversion treatment may be controlled by properly selecting the applying conditions, the irradiation conditions of vacuum UV ray, and the like. For example, the film thickness, density, and the like of the barrier layer may be controlled by properly selecting the irradiation method of vacuum UV ray from the continuous irradiation, the irradiation that is divided into several times, so-called pulse irradiation, in which the irradiations in several times are short time, and the like.

In addition, the film density of the barrier layer may be properly selected according to the purposes. For example, the film density of the barrier layer is in the range of 1.5 to 2.6 g/cm³. When being in such a range, the compactness of film is improved, and thus, it is possible to prevent the deterioration of gas barrier properties, and the deterioration of the film under the conditions of a high temperature and high humidity.

In addition, the second inorganic layer has proper surface smoothness. In detail, for the surface smoothness of the second inorganic layer, the centerline average roughness (Ra) of the second inorganic layer is 50 nm or less or 10 nm or less. The lower limit of the centerline average roughness (Ra) of the second inorganic layer is not particularly limited, but practically, 0.01 nm or more, or 0.1 nm or more. When the second inorganic layer has such a Ra, the second inorganic layer favorably responds to the concavo-convex surface thereof to closely form the second barrier layer on the second inorganic layer. For this reason, the second barrier layer covers more effectively the cracks or the defects such as a dangling bond, which are generated on the second inorganic layer to form a dense surface. Therefore, it is possible to more effectively suppress and prevent the decrease in the gas barrier properties (for example, low oxygen permeability and high vapor barrier properties) under the conditions of a high temperature and high humidity. In addition, in the present specification, the centerline average roughness (Ra) of the barrier layer is the value measured by the method to be described in the following Examples.

A method for forming the second inorganic layer having the above-described centerline average roughness (Ra) is not particularly limited. For example, by the method for installing the following control layer between a substrate and the second inorganic layer; the method for installing an intermediate layer (especially, the following first inorganic layer) between the second inorganic layer and the second barrier layer; the method for controlling the surface roughness by the selection of a substrate; the method for controlling the surface roughness of a basal layer; and the method for performing the surface treatment before applying a PHPS layer, it is possible to control the centerline average roughness (Ra) of the second inorganic layer in the above-described range.

The degree of the conversion treatment may be confirmed by obtaining the composition ratio of the respective atoms such as a silicon (Si) atom, a nitrogen (N) atom, and an oxygen (O) atom by analyzing the formed second inorganic layer with XPS.

In addition, the gas barrier film obtained by the repairing effect of the second barrier layer has high gas barrier properties. Therefore, the gas barrier properties of the second inorganic layer may be slightly low. In more detail, the vapor permeability of the second inorganic layer is 0.5 g/m²·day or less or 0.2 g/m²·day or less. In addition, the above-described “vapor permeability” is the value measured by the method to be described in Examples.

[Functional Layer]

In addition, the gas barrier film in accordance with one or more embodiments of the invention may have various functional layers, in addition to the inorganic layer in accordance with one or more embodiments of the invention and the substrate in accordance with one or more embodiments of the invention. Examples of the functional layers may include an optical functional layer such as an antireflection layer, a polarizing layer, a color filter, or a layer with improved light-extraction efficiency; a mechanical functional layer such as a hard coat layer, or a stress-relaxation layer; an electrical functional layer such as an antistatic layer or a conductive layer; an antifogging layer; an antifouling layer; a layer to be printed; and the like.

In addition, on the plastic film side that is opposed to the side having the barrier layer that satisfies the conditions of embodiments of the invention formed, the gas barrier laminate layer having the barrier layer o, which is at least laminated with the inorganic layer and the organic layer may be installed. The gas barrier laminate layer prevents the invasion of water molecular from the opposite side of the film, and prevents the stress concentration in the barrier layer or breaking by suppressing the dimensional change of the gas barrier film, and as a result, increases the durability thereof.

As described above, all of the substrate, the first inorganic layer, the second inorganic layer, the functional layers, and other thicknesses may be arbitrarily controlled by controlling the concentration or applying rate of a coating solution.

[Performance of Gas Barrier Film]

The gas barrier film in accordance with one or more embodiments of the invention exhibits excellent gas barrier properties. The vapor permeability of the gas barrier film in accordance with one or more embodiments of the invention may obtain 0.01 g/m²·day or less, 0.005 g/m²·day or less, 0.003 g/m²·day or less, or 0.001 g/m²·day or less. In addition, the gas barrier film in accordance with one or more embodiments of the invention exhibits excellent coherency. In other words, the coherency between the organic layer and the inorganic layer, which constitute the barrier layer, is excellent. The excellent vapor permeability and coherency are maintained after the gas barrier film is bended in several times. Therefore, the barrier film is suitably used for a flexible image display device, and the like.

[Electronic Device]

The gas barrier film in accordance with one or more embodiments of the invention may be used for the device with deteriorated performance caused by chemical components (oxygen, water, nitrogen oxide, sulfur oxide, ozone, and the like) in the air. Examples of the electronic device may include, for example, electronic devices such as an organic EL element, a liquid crystal display element (LCD), a thin-film transistor, a touch panel, an electronic paper, and a solar battery (PV). From the viewpoint of more effectively obtaining the effects embodiments of the invention, the gas barrier film is used for an organic EL element or a solar battery, and used for an organic EL element.

(Organic EL Element)

Examples of the organic EL element using the gas barrier film are described in JP 2007-30387 A in detail.

### EXAMPLES

The effects will be described using the following Examples and Comparative Examples. However, the technical range of embodiments of the invention is not limited to the following Examples.

### Example 1-1

### Substrate

As a substrate, a biaxial stretching polyethylene naphthalate film (PEN film, thickness: 100 μm, width: 350 mm, manufactured by Teijin DuPont Films Japan Limited, Trade Name: “Teonex Q65FA”) was used.

[Formation of Smoothing Layer, Anchor Coat Layer]

A UV curable organic/inorganic hybrid hard coating material manufactured by JSR Corporation, OPSTAR Z7501, was coated on the easily adhesive surface of the substrate with a wire bar so as to have a film thickness of 4 μm after drying; dried under the drying conditions of 80° C. for 3 minutes; and cured under the curing condition of 1.0 J/cm² by use of a high pressure mercury lamp under an air atmosphere to form a smoothing layer.

At this time, the maximum cross-sectional height Rt (p) exhibiting the surface roughness was 16 nm.

In addition, the surface roughness was calculated from a cross-sectional curve of unevenness continuously measured with a detection device having a sensing pin with a tiny tip radius by AFM (atomic force microscope manufactured by Digital Instruments) and measurements were carried out in a zone of 30 μm in a measurement direction by the sensing pin with a tiny tip radius many times to obtain an average roughness relating to amplitude of fine unevenness.

[Formation of First Inorganic Layer (Silicon Oxycarbide (SiOC))]

For the device illustrated in FIG. 2, a substrate was installed in the device, and then, a barrier thin-film layer was formed on the substrate to have the thickness of 300 nm under the following film-forming conditions (plasma CVD conditions). The carbon distribution curve of carbon atom included in the obtained first inorganic layer satisfies the above-described conditions (i) and (ii).

(Film-Forming Conditions)

Supplying amount of raw material gas (hexamethyldisiloxane (HMDSO)): 50 sccm (Standard Cubic Centimeter per Minute)

Supplying amount of oxygen gas (O₂): 500 sccm

Vacuum degree in vacuum chamber: 3 Pa

Applying powder from power supply for plasma generation: 0.8 kW

Frequency of power supply for plasma generation: 70 kHz

Conveying rate of film: 0.5 m/min

[Formation of Silicon Nitride Nanoparticles]

The silicon nitride particles (Product NO. 636703, manufactured by Sigma-Aldrich Co., Ltd.) as aggregation fine particles to be pulverized and dispersed were mixed so as to be the concentration of 5% by mass using methyl ethyl ketone (MEK) as a dispersing medium, and then, uniformly mixed using a disperser.

Next, using a bead mill (“SUPER APEX MILL SAM-05 type” manufactured by Kotobuki Engineering & Manufacturing Co., Ltd.) as a disperser, the coarse aggregation fine particles were first crushed with a homogenizer to obtain a particles-dispersed undiluted solution. The particles-dispersed undiluted solution was put in a 0.5 L stirring vessel made of zirconia in a bead mill, and then, the stirring particles having the particle diameter of 20 μm, which was made of zirconia, were put to be 70 vol %.

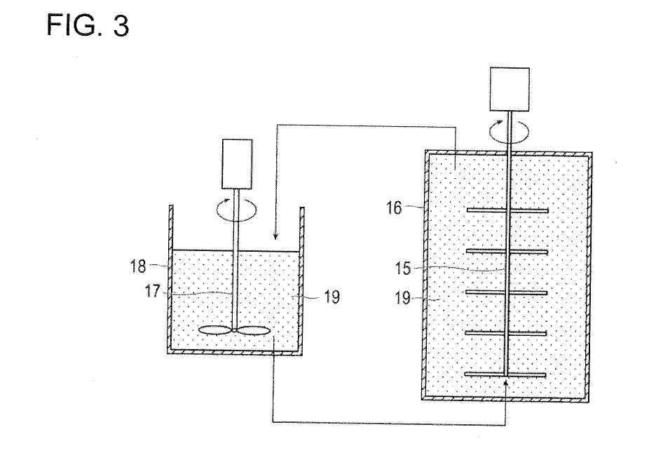

FIG. 3 illustrates a pulverizing•dispersing device by a circulating system using a bead mill and a dispersion tank. While the particles-dispersed undiluted solution 19 was circulated between the stirring vessel 16 of the bead mill installed with a stirring wing 15 and the dispersion tank 18 installed with a stirring blade 17, the stirring wing 15 of the bead mill was operated in the number of revolutions of 3000 rpm to stir the particles-dispersed undiluted solution 19. By this operation, the aggregation fine particles in the particles-dispersed undiluted solution 19 were pulverized into stirring particles, and also, at the same time, the treatment for pulverizing and dispersing the pulverized fine particles was performed to be the average particle diameter as listed in Table 1. The average particle diameter (spherical equivalent diameter) of silicon nitride nanoparticles obtained by the pulverizing•dispersing treatment as described above was measured by using a concentrated system-particle size analyzer “FPAR-1000” manufactured by Otsuka Electronics Co., Ltd. and then, the dispersibility was measured. The results of the average particle diameter (spherical equivalent diameter are listed in Table 1.

[Preparation of Nanoparticles-Containing and Polysilazane-Containing Coating Solution]

A dibutyl ether solution (NN120-20 manufactured by AZ Electronic Materials Co., Ltd.) including 40% by mass of perhydropolysilazane without a catalyst and a dibutyl ether solution (NAX120-20 manufactured by AZ Electronic Materials Co., Ltd.) including 40% by mass of perhydropolysilazane with an amine catalyst were mixed in the ratio of 4:1, and then, diluted and adjusted with the solvent that was mixed to be the solvent mass ratio of dibutyl ether and 2,2,4-trimethylpentane of 65:35 to be 5% by mass of the solid content of the coating solution. 5% by mass of the silicon nitride nanoparticles dispersion solution having the average particle diameter of 11 nm was added to such a solution to prepare a coating solution.

The coating solution thus prepared was applied on the vapor deposition film, and then, the conversion (silica conversion) treatment was performed under the following conditions to form the second inorganic layer having the thickness of 100 nm.

[Formation of Barrier Layer: Conversion (Silica Conversion) Treatment of Polysilazane Layer by UV Ray]

To the polysilazane layer thus formed, according to the following method, the silica conversion treatment was performed under the condition of a dew-point temperature of −8° C. or lower.

(UV Ray Irradiation Device)

Device: Excimer irradiation device manufactured by M. D. COM. Inc. MODEL: MECL-M-1-200

Irradiation wavelength: 172 nm

Lamp enclosed gas: Xe

(Irradiation Condition)

To the substrate formed with a polysilazane layer fixed on the operating stage, the conversion treatment of polysilazane was performed under the following conditions to form a barrier layer.

Light intensity of excimer lamp: 200 mW/cm² (172 nm)

Distance between sample and light source: 1 mm

Stage heating temperature: 95° C.

Oxygen concentration in irradiation device: 500 ppm

Vapor concentration in irradiation device: 50 ppm

Irradiation time of excimer lamp: 10 seconds

### Example 1-2

A gas barrier film was manufactured in the same method as Example 1-1, except that the average particle diameter of silicon nitride nanoparticle added in the polysilazane-containing coating solution was 26 nm in Example 1-1.

### Example 1-3

A gas barrier film was manufactured in the same method as Example 1-1, except that the average particle diameter of silicon nitride nanoparticle added in the polysilazane-containing coating solution was 44 nm in Example 1-1.

### Example 1-4

A gas barrier film was manufactured in the same method as Example 1-1, except that the average particle diameter of silicon nitride nanoparticle added in the polysilazane-containing coating solution was 53 nm in Example 1-1.

### Example 1-5

A gas barrier film was manufactured in the same method as Example 1-1, except that the average particle diameter of silicon nitride nanoparticle added in the polysilazane-containing coating solution was 95 nm in Example 1-1.

### Example 1-5

A gas barrier film was manufactured in the same method as Example 1-1, except that the average particle diameter of silicon nitride nanoparticle added in the polysilazane-containing coating solution was 104 nm in Example 1-1.

### Example 1-7

A gas barrier film was manufactured in the same method as Example 1-1, except that the titanium oxide nanoparticles having the average particle diameter of 5 nm as a nanoparticle were added in the polysilazane-containing coating solution in Example 1-1.

### Example 1-8

A gas barrier film was manufactured in the same method as Example 1-7, except that the average particle diameter of titanium nitride nanoparticle added in the polysilazane-containing coating solution was 50 nm in Example 1-7.

### Example 1-9

A gas barrier film was manufactured in the same method as Example 1-7, except that the average particle diameter of titanium nitride nanoparticle added in the polysilazane-containing coating solution was 100 nm in Example 1-7.

### Example 1-10

A gas barrier film was manufactured in the same method as Example 1-1, except that the alumina nanoparticles having the average particle diameter of 5 nm as a nanoparticle were added in the polysilazane-containing coating solution in Example 1-1.

### Example 1-11

A gas barrier film was manufactured in the same method as Example 1-10, except that the average particle diameter of alumina nanoparticle added in the polysilazane-containing coating solution was 50 nm in Example 1-10.

### Example 1-12

A gas barrier film was manufactured in the same method as Example 1-10, except that the average particle diameter of alumina nanoparticle added in the polysilazane-containing coating solution was 100 nm in Example 1-10.

### Example 1-13

A gas barrier film was manufactured in the same method as Example 1-1, except that the zirconia nanoparticles having the average particle diameter of 5 nm as a nanoparticle were added in the polysilazane-containing coating solution in Example 1-1.

### Example 1-14

A gas barrier film was manufactured in the same method as Example 1-13, except that the average particle diameter of zirconia nanoparticle added in the polysilazane-containing coating solution was 50 nm in Example 1-13.

### Example 1-15

A gas barrier film was manufactured in the same method as Example 1-13, except that the average particle diameter of zirconia nanoparticle added in the polysilazane-containing coating solution was 100 nm in Example 1-13.

### Example 1-16

A gas barrier film was manufactured in the same method as Example 1-1, except that the zinc oxide nanoparticles having the average particle diameter of 5 nm as a nanoparticle were added in the polysilazane-containing coating solution in Example 1-1.

### Example 1-17

A gas barrier film was manufactured in the same method as Example 1-16, except that the average particle diameter of zinc oxide nanoparticle added in the polysilazane-containing coating solution was 50 nm in Example 1-16.

### Example 1-18

A gas barrier film was manufactured in the same method as Example 1-16, except that the average particle diameter of zinc oxide nanoparticle added in the polysilazane-containing coating solution was 100 nm in Example 1-16.

### Comparative Example 1-1

A gas barrier film was manufactured in the same method as Example 1-1, except that the silicon nitride nanoparticles were not added in the polysilazane-containing coating solution in Example 1-1.

### Example 2-1

A gas barrier film was manufactured in the same method as Example 1-1, except that a plastic film was manufactured by the following method, and by using the silicon nitride nanoparticles having the particle diameter of 32 nm, the film thickness of the first inorganic layer (silicon oxycarbide film (SiOC)) was to be 150 nm.

The polyethylene naphthalate film (PEN film, thickness of 100 μm, manufactured by Teijin DuPont Films Japan Limited, Product Name: Teonex Q65FA) was cut to 20 cm square, and then, a barrier layer was formed on the smoothing side thereof in the same method as Example 1-1. And then, the evaluation thereof was performed.

### Example 2-2

A gas barrier film was manufactured in the same method as Example 2-1, except that the first inorganic layer (silicon oxide film (SiO₂)) was manufactured by the following method.

On one side of the plastic film, a SiO₂ film was formed by the plasma CVD method under the following film-forming conditions.

Film-Forming Conditions

Supplying amount of raw material gas (hexamethyldisiloxane (HMDSO)): 50 sccm

Supplying amount of oxygen gas (O₂): 1000 sccm

Vacuum degree in vacuum chamber: 3.5 Pa

Applying powder from power supply for plasma generation: 0.5 kW

Frequency of powder supply for plasma generation: 13.56 MHz

Conveying rate of film: 0.5 m/min

### Example 2-3

A gas barrier film was manufactured in the same method as Example 2-1, except that the first inorganic layer (alumino silicate film (SiAlO)) was manufactured by the following method.

A splice roll was charged in a roll-to-roll sputter coater. The pressure in a film-forming chamber was reduced to 2×10⁻⁶ torr with a pump. A SiAlO inorganic oxide layer having the thickness of 150 nm was deposited on a substrate by performing the reaction sputtering of Si—Al (95/5) Target (article available from Academy Precision Materials), using the web rate of 0.43 meter/min, and the gas mixture including 51 sccm of argon and 30 sccm of oxygen with 2 kW, 600 V, and the pressure of 1 millitorr.

### Example 2-4

A gas barrier film was manufactured in the same method as Example 2-2, except that the first inorganic layer (hydrogenated silicon nitride film (SiNH)) was manufactured by the following method.

Film-Forming Conditions

A first inorganic layer (hydrogenated silicon nitride film (SiNH) (N component except Si: 97 mol %)) was formed in the same conditions as Example 2-2, except that the raw material gas of the following plasma CVD raw material gas formulation 1 was introduced.

Plasma CVD Raw Material Gas Formulation 1

Silane gas: 25 sccm

Ammonia gas: 15 sccm

Nitrogen gas: 200 sccm

Plasma CVD Raw Material Gas Formulation 2

Silane gas: 25 sccm

Ammonia gas: 50 sccm

Nitrogen gas: 165 sccm

### Example 2-5

A barrier layer was manufactured in the same method as Example 2-1, except that a first inorganic layer (acid silicon nitride film (SiON)) was manufactured by the following method.

Using a general CVD device (manufactured by SAMCO Inc., PD-220 NA) for film-forming by a CCP-CVD method, the acid silicon nitride film (SiON) having the film thickness of 150 nm as a gas barrier film was formed on a substrate.

As a substrate, a polyethylene naphthalate film (PEN film, thickness of 100 μm, manufactured by Teijin DuPont Films Japan Limited, Product Name: Teonex Q65FA) was used. In addition, the area of the substrate was 300 cm².

A substrate was set in a predetermined position of a vacuum chamber, and then, the vacuum chamber was closed. Since then, the exhaust was performed in the vacuum chamber, and at the time of the pressure of 0.01 Pa, as a reaction gas, a silane gas (5% nitrogen dilution) and an oxygen gas (5% nitrogen dilution) were introduced. In addition, the nitrogen gas of the flow rate of the silane gas of 50 sccm and the flow rate of the oxygen gas of 5 sccm was used. In addition, the exhaust in the vacuum chamber was adjusted so as to be the pressure of 100 Pa in the vacuum chamber.

### Comparative Example 2-1

A barrier film was manufactured in the same method as Example 2-1, except that the polysilazane conversion film (PHPS) that was the second inorganic layer of the present application was manufactured by the following method, instead of the vapor deposition film as the first inorganic layer.

Formation of Polysilazane Coating Film

A vapor deposition film was not formed on the surface of a substrate, but the polysilazane-containing coating solution prepared by using Si₃N₄ having the particle diameter of 32 nm was applied on the surface of the substrate with a wireless bar so as to have the (average) film thickness of 300 nm after drying, and then, the dehumidification treatment thereof was performed by drying it under the atmosphere of the temperature of 85° C. and the humidity of 55% RH for 1 minute and also maintaining it under the atmosphere of the temperature of 25° C. and the humidity of 10% RH (dew-point temperature of −8° C.) for 10 minutes to form a polysilazane layer.

(Formation of Barrier Layer: Conversion (Silica Conversion) Treatment of Polysilazane Layer by UV Ray)

Next, to the above-formed polysilazane layer, the conversion (silica conversion) treatment was performed under the condition of the dew-point temperature of −8° C. according to the following method.

Device: Excimer irradiation device manufactured by M. D. COM. Inc. MODEL: MECL-M-1-200

Irradiation wavelength: 172 nm

Lamp enclosed gas: Xe

Conversion Treatment Conditions

The conversion treatment was performed to the substrate with the polysilazane layer fixed on the operation stage under the following conditions to form a barrier layer.

Light intensity of excimer lamp: 130 mW/cm² (172 nm)

Distance between sample and light source: 1 mm

Stage heating temperature: 70° C.

Oxygen concentration of irradiation device: 500 ppm

Irradiation time of excimer lamp: 10 seconds

### Comparative Example 2-2

A barrier film was manufactured in the same method as Example 2-1, except that the nanoparticles were not added to the polysilazane-containing coating solution.

[Evaluation 1: Evaluation of Gas Barrier Properties]

The gas barrier properties of the above-produced gas barrier film were evaluated by measuring vapor permeability as follows.

(Device for Preparing Sample for Measuring Vapor Permeability)

Vapor deposition device: vacuum vapor deposition device JEE-400 manufactured by JEOL Ltd.

Constant temperature and humidity oven: Yamato Humidic Chamber IG47M

(Raw Material)

Metal that is corroded by reacting with water: calcium (granule)

Vapor impermeable metal: aluminum (□3 to 5 mm, granule)

(Preparation of Sample for Measuring Vapor Permeability)

On the surface of the barrier layer of the gas barrier film produced by using a vacuum vapor deposition device (vacuum vapor deposition device JEE-400, manufactured by JEOL Ltd.), the metal calcium having the size of 12 mm×12 mm through a mask was deposited so as to have the vapor deposition film thickness of 80 nm.

Since then, the mask was removed in the state of vacuum, aluminum, vapor impermeable metal, was deposited on the whole one side of a sheet, and then, the tentative sealing was performed. Next, the state of vacuum was removed, and then, transferred under the dried nitrogen gas atmosphere. A quartz glass having the thickness of 0.2 mm was attached on the deposition side of aluminum through a UV ray curing resin (manufactured by Nagase ChemteX Corp.) for sealing, and the resin was cured and attached for the practical sealing by irradiating with UV ray to prepare the sample for measuring vapor permeability.

The obtained sample (cell for evaluation) was stored under a high temperature and high humidity of 60° C. and 90% RH using the constant temperature and humidity oven, Yamato Humidic Chamber IG47M, and then, based on the method disclosed in JP 2005-283561 A, the amount of water penetrated through the cell was calculated from the corrosion amount of metal calcium.

[Evaluation 2: Long-Term Preservability Evaluation]

After the produced gas barrier film was stored for 30 days under the condition of the high temperature and high humidity of 85° C. and 90% RH, the sample for evaluating the vapor barrier properties was prepared, and then, the degree of deterioration resistance (%) was calculated from the following Equation. Since then, the vapor barrier properties were evaluated.

$$\text{?} \\ \text{?} \text{indicates text missing or illegible when filed} \qquad [ Equation 3 ]$$

As a number of the following ranking increases, the long-term preservability is good.

5: The degree of deterioration resistance was 90% or more.

4: The degree of deterioration resistance was 80% or more and less than 90%.

3: The degree of deterioration resistance was 60% or more and less than 80%.

2: The degree of deterioration resistance was 30% or more and less than 60%.

1: The degree of deterioration resistance was less than 30%.

TABLE 1

| | | Particle | | |
|---|---|---|---|---|
| | | diameter | WVTR | Long-term |
| | Nanoparticle | (nm) | (g/m² · day) | preservability |
| Example 1-1 | Si₃N₄ | 11 | 1.1 × 10⁻⁵ | 5 |
| Example 1-2 | Si₃N₄ | 26 | 1.2 × 10⁻⁵ | 5 |
| Example 1-3 | Si₃N₄ | 44 | 1.6 × 10⁻⁵ | 5 |
| Example 1-4 | Si₃N₄ | 53 | 1 × 10⁻⁴ | 5 |
| Example 1-5 | Si₃N₄ | 95 | 1.2 × 10⁻⁴ | 4 |
| Example 1-6 | Si₃N₄ | 104 | 3.1 × 10⁻³ | 3 |
| Example 1-7 | TiO₂ | 5 | 1.2 × 10⁻⁵ | 5 |
| Example 1-8 | TiO₂ | 50 | 1.8 × 10⁻⁵ | 5 |
| Example 1-9 | TiO₂ | 100 | 3.5 × 10⁻³ | 3 |
| Example 1-10 | Al₂O₃ | 5 | 1.3 × 10⁻⁵ | 5 |
| Example 1-11 | Al₂O₃ | 50 | 1.9 × 10⁻⁵ | 5 |
| Example 1-12 | Al₂O₃ | 100 | 3.4 × 10⁻³ | 3 |
| Example 1-13 | ZrO₂ | 5 | 1.5 × 10⁻⁵ | 5 |
| Example 1-14 | ZrO₂ | 50 | 1.7 × 10⁻⁵ | 5 |
| Example 1-15 | ZrO₂ | 100 | 3.6 × 10⁻³ | 3 |
| Example 1-16 | ZnO | 5 | 1.4 × 10⁻⁵ | 5 |
| Example 1-17 | ZnO | 50 | 1.6 × 10⁻⁵ | 5 |
| Example 1-18 | ZnO | 100 | 3.5 × 10⁻³ | 3 |
| Comparative | — | — | 1.25 × 10⁻² | 1 |
| Example 1-1 | | | | |

TABLE 2

| | Vapor | Film thickness | | |
|---|---|---|---|---|
| | deposition | of first | | |
| | barrier | inorganic layer | WVTR | Long-term |
| | type | (nm) | (g/m² · day) | preservability |
| Example 2-1 | SiOC | 150 | 1.3 × 10⁻⁵ | 5 |
| Example 2-2 | SiO₂ | 150 | 1.1 × 10⁻⁵ | 4 |
| Example 2-3 | SiAlO | 150 | 1.3 × 10⁻⁵ | 4 |
| Example 2-4 | SiNH | 150 | 1.3 × 10⁻⁵ | 5 |
| Example 2-5 | SiON | 150 | 1.4 × 10⁻⁵ | 4 |
| Comparative | PHPS | 150 | 3.2 × 10⁻³ | 1 |
| Example 2-1 | | | | |
| Comparative | SiOC* | 150 | 4.8 × 10⁻² | 1 |
| Example 2-2 | | | | |

*For Example 2-1, the gas barrier film having the second inorganic layer without nanoparticles

As listed in Table 1, the gas barrier films (Example 1-1 to Example 1-18) in accordance with one or more embodiments of the invention, which had the barrier layer including nanoparticles, exhibited very low vapor permeability as compared with the gas barrier film (Example 1-19) without nanoparticles. As described above, the effect on improving the gas barrier properties a lot by using the barrier layer including the nanoparticles as the barrier layer was not limited to the silicon nitride nanoparticles, but also, the effect was similar to many nanoparticles of metal oxide and metal nitride. In addition, when the average particle diameter of nanoparticles was at least about 5 to 100 nm, it was possible to obtain sufficient gas barrier properties, and thus, the long-term preservability was sufficient.

In addition, as listed in Table 2, the gas barrier film in accordance with one or more embodiments of the invention, which had the barrier layer including nanoparticles, exhibited good gas barrier properties and vapor permeability, even though the materials for the first inorganic layer were changed. In addition, when the first inorganic layer was formed by the vapor deposition method (Example 2-1 to Example 2-5), the gas barrier properties became good, and thus, the long-term preservabilities were excellent, as compared with the case of substituting the first inorganic layer for the barrier layer obtained by converting the polysilazane coating film (Comparative Example 2-1). This was because the coherency between the substrate and the barrier layer became good by forming the first inorganic layer using the vapor deposition method.

In addition, the present application is based on Japanese Patent Application No. 2013-096587 filed on May 1, 2013 in the Japanese Intellectual Property Office, the disclosure of which is incorporated herein by reference.

Although the disclosure has been described with respect to only a limited number of embodiments, those skilled in the art, having benefit of this disclosure, will appreciate that various other embodiments may be devised without departing from the scope of the invention. Accordingly, the scope of the invention should be limited only by the attached claims.

### REFERENCE SIGNS LIST

1 Gas barrier film
2 Substrate
3 CVD layer
101 Plasma CVD device
102 Vacuum chamber
103 Cathode electrode
105 Susceptor
106 Heating medium circulating system
107 Vacuum exhaust system
108 Gas introducing system
109 High frequency power supply
160 Heating-cooling device
110 Substrate
31 Producing device
32 Delivery roller
33, 34, 35, 36 Conveying roller
39, 40 Film-forming roller
41 Gas supply tube
42 Power supply for plasma generation
43, 44 Magnetic field generating apparatus
45 Winding roller
15 Stirring wing
16 Stirring vessel of bead mill
17 Stirring blade
18 Dispersion tank
19 Particles-dispersed undiluted solution

1. A gas barrier film comprising:
a first barrier layer formed by a vapor deposition method on at least one side of a substrate; and
a second barrier layer formed on the first barrier layer by converting a polysilazane coating film,
wherein the polysilazane coating film includes at least one type of nanoparticles among metal oxide and metal nitride, and
the polysilazane coating film is converted by irradiating the polysilazane coating film with vacuum UV ray having a wavelength of 200 nm or less.

2. The gas barrier film according to claim 1, wherein the first barrier layer comprises:
one selected from a group consisting of oxide, nitride, oxynitride, oxycarbide, or oxynitride carbide; and
at least one selected from a group consisting of silicon oxynitride (SiON), silicon nitride (SiN), hydrogenated silicon nitride (SiNH), silicon oxycarbide (SiOC), silicon oxide (SiO2), aluminum silicate (SiAlO), and silicon oxynitride-carbide (SiONC).

3. The gas barrier film according to claim 1, wherein the nanoparticles comprise:
at least one selected from a group consisting of oxide and nitride; and
at least one element selected from a group consisting of Si, Ti, Al, Zr, Zn, Ba, Sr, Ca, Mg, V, Cr, Mo, Li, and Mn, wherein an average particle diameter of the nanoparticles is 5 to 100 nm as a spherical equivalent diameter.

4. The gas barrier film according to claim 1, wherein an average particle diameter of the nanoparticles is 5 to 100 nm as a spherical equivalent diameter, and the nanoparticles comprise at least one selected from a group consisting of Si3N4, TiO2, Al2O3, ZrO2, ZnO, BaO, SrO, CaO, MgO, VO, CrO, MoO2, and LiMnO2.

5. A method for producing a gas barrier film, the method comprising:
forming a first barrier layer on at least one side of a substrate by a vapor deposition method;
forming a polysilazane coating film by applying and drying a polysilazane-containing coating solution including at least one type of nanoparticles on the first barrier layer; and
converting the polysilazane coating film by irradiating the polysilazane coating film with vacuum UV ray having a wavelength of 200 nm or less,
wherein the nanoparticles comprise one selected from a group consisting of a metal oxide and a metal nitride.

6. An electronic device comprising the gas barrier film according to claim 1.

7. A gas barrier film produced by the method according to claim 5.
